(19) United States
(12) Patent Application Publication
(10) Pub. No.: US 2008/0230111 A1
(43) Pub. Date: Sep. 25, 2008

(54) Solar Collector Comprising a Heat Engine

(75) Inventor: Jurgen Uehlin, Schopfheim (DE)

Correspondence Address: VOLPE AND KOENIG, P.C., UNITED PLAZA, SUITE 1600, 30 SOUTH 17TH STREET, PHILADELPHIA, PA, 19103, US

(73) Assignee: DURLUM-LEUCHTEN GMBH LICHTTECHNISCHE SPEZIALFABRIK, Schopfheim (DE)

(21) Appl. No.: 12/093,352

(22) PCT Filed: Nov. 14, 2006
(86) PCT No.: PCT/DE2006/001991

§ 371 Date: May 12, 2008

(30) Foreign Application Priority Data
Nov. 15, 2005 (DE) 102005054366.9

(51) Int. Cl. H01L 31/058; F01D 15/10; F24J 2/32; F24J 2/10

(52) U.S. Cl. 136/248; 60/641.8; 126/635; 126/643; 126/684

(57) ABSTRACT

A method for generating energy from concentrated solar radiation by photovoltaic and thermally useable solar cells in which the absorbed heat radiation evaporates a fluid which drives a turbine connected to a generator.

### BACKGROUND

The present invention relates to a solar collector with photovoltaic and thermally usable solar cells provided with at least one concentrating reflector.

Such photovoltaic modules serve to directly convert solar radiation into electric energy and/or heat.

The spectrum of electromagnetic radiation emitted by the sun can only be used to a small part for conversion into electricity, because the sensitivity of the voltaic effective solar cells is only given at a range from approximately 350-900 nm. The energy of UV-radiation below 350 nm and infrared radiation above 900 nm causes heating of the cells. Their effectiveness is at maximum at temperatures of approximately −20° C., and at 80° C. it is so low that the production of electricity is no longer profitable. At even higher temperatures the cells may be damaged, with the values strongly depending on the respective type of solar cells.

This problem drastically increases when the solar cells are operated with concentrated light. At a concentration factor above 10, a few minutes of a clear summer's day are sufficient to reach temperatures that cause destructive effects. These cells must be cooled.

In prior art, it is attempted to dissipate the heat either via large area cooling elements or to connect the solar cells and/or their carriers to a cooling element with a refrigerant flowing through it. It is also known to allow a refrigerant to flow around the solar cells in order to improve the heat transfer, causing a multitude of problems with regard to corrosion and short circuit proofing and with a considerable portion of the electric energy generated by the cells being necessary to operate the circulating pump of the refrigerant.

### SUMMARY

The object of the invention is to provide a method that can be produced easily and at low cost and which improves the effectiveness of solar collectors utilizing it.

The object is attained in claim 1 according to the invention. Additional features are described in claims 2 and 3 and the dependent claims.

The present invention allows the effective, combined use of the global solar radiation via photovoltaic solar cells and solar thermally driven heat engines. The spectral separation of the collected radiation occurs preferably but not exclusively such that the flat photovoltaic cells are radiated as evenly as possible with the spectrum they can use and the solar-thermal cells linearly with the portion of the radiation separated. The stronger the concentration of the thermal radiation and accordingly narrow the thermally radiated surface the higher the temperature that can be reached and proportional thereto the effectiveness of the heat engine arranged downstream. The separation of the radiation usable for photovoltaics is preferably caused by partially permeable spectral filters, which additionally leads to the advantageous effect that the photovoltaic cells remain relatively cool and the thermal radiation can be concentrated on the solar-thermal cells via optically effective means, such as lenses, mirrors, reflectors, etc.

Another method to keep undesired heat radiation from the solar cells is the spectral filtering of the impinging radiation via a transparent refrigerant, which moistens the cells at least in the radiated area or flows around it, converting the radiation not usable for photovoltaic conversion into heat, and transporting it into a heat exchanger cooled at least partially by evaporative heat loss. When the refrigerant is neither water nor water-like, for example mono-propylene glycol or tri-propylene glycol, it must be guided in a closed container or circuit. If water is used as the filtration or heat exchanging fluid, after being charged with heat, it can be fed to open evaporation.

The heat carrying fluid evaporated in the solar-thermal cells must be condensed after the work is done. According to the invention, this process occurs predominantly by way of open evaporation in coolable containers, which preferably are formed and/or supported at least partially by the collectors and/or solar cells and/or their carriers. The removal of heat by way of open evaporation is several times greater than by convection or radiation.

When the reflector area is enlarged to increase the concentration factor, simultaneously the useable cooling area is enlarged as well. Due to the fact that the sensitive surfaces of the solar cells and/or the reflecting side of the concentrators are aligned towards the sun their shaded rear side can be used as the evaporation area or the carrier of an evaporation arrangement.

The medium to be evaporated is water, preferably in the form of rain water and/or tap water. Substances promoting evaporation, for example a tenside, can be added to it. The water supply occurs preferably via the capillary effect of porous materials, which for this purpose immerse into the liquid stored in a gutter, tub, or a similar collection vessel, which is arranged preferably below and/or above the evaporation devices. Additionally or alternatively the evaporation devices may also be sprayed with water, which is fed thereto under pressure via a pump or from the tap water line. In order to increase the evaporation performance the evaporation area may be formed from highly porous material having a large surface. Particularly suitable are felts, non-woven webs, fibrous mats, foams comprising organic and/or inorganic materials, preferably metallic foams, kilned earthenware, sintered elements, ceramic plates, and the like.

In the event evaporators are assembled at a distance of few centimeters from each other or staggered in a slightly conical fashion, a chimney effect develops intensifying the cooling effect. In a recumbent arrangement of modules on an inclined surface it is advantageous for rear ventilation to be provided.

### BRIEF DESCRIPTION OF THE DRAWINGS

In the following the invention is explained in greater detail using schematic exemplary embodiments. Shown are:

FIG. 1 a cross-sectional view through a solar collector according to the invention.

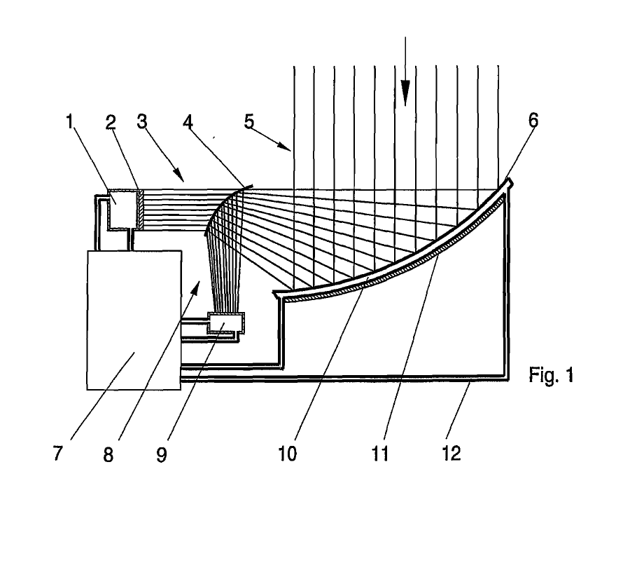

### DETAILED DESCRIPTION OF THE PREFERRED EMBODIMENT

The solar radiation 5 is deflected by the reflector 6 to the beam splitter 4, which separates the thermally usable frequencies 8 in the UV- and infrared range and deflects them to the thermally effective solar cell 9, which directly or indirectly evaporates the heat carrier for a heat engine 7. The photo-voltaic usable radiation 3 is converted into electricity by the solar cell 2, which is connected to a cooling unit 1. The reflector 6 connected to the heat engine 7 via a pipeline 12 is used as the condenser, with its cooling performance being increased by the coating 11 applied at its rear side, provided with a porous and/or large surface and preferably of a dark color, which is moistened with an easily evaporating liquid, preferably water. The cooling unit can be connected to the cooling chamber 10 of the reflector 6 via the pipeline 12.

1. A method for generating energy from concentrated solar radiation via photovoltaic and thermally useable solar cells of a solar collector, comprising evaporating a heat carrying fluid with absorbed radiation, driving a turbine connected to a generator producing electric energy, and cooling of the solar collector occurs by open evaporation of water.

2. A method for energy generation from concentrated solar radiation via photo voltaic and thermally usable solar cells, comprising evaporating a heat carrying fluid with absorbed radiation, driving a turbine connected to a generator producing electric energy, condensation of and condensing the heat carrying fluid by open evaporation of water.

3. A method for energy generation from concentrated solar radiation via photo voltaic and thermally usable solar cells of a solar collector, comprising evaporating a heat carrying fluid with absorbed radiation, driving a turbine connected to a generator producing electric energy, and cooling the solar collector by open evaporation of water at least on a shaded side of a reflector thereof.

4. A method for energy generation from concentrated solar radiation via photo voltaic and thermally usable solar cells with a reflector, comprising evaporating a heat carrying fluid with absorbed radiation, driving a turbine connected to a generator producing electric energy, condensation of and condensing the heat carrying fluid by open evaporation of water at least on a shaded side of the reflector.

5. A method according to claim 1, wherein
the cooling occurs by open condensation evaporation of water in a porous material.

6. A method according to claim 3, wherein
the cooling occurs by open evaporation of water in a porous material on the shaded side of the solar collector and/or concentrator.

7. A method according to claim 2, wherein
the cooling occurs by open evaporation of water in a porous material.

8. A method according to claim 1, wherein
the cooling water first moistens a photovoltaic one of the solar cells on a radiated side and is then fed to an evaporation area.

9. A method according to claim 1, wherein
the cooling water first flows around a photovoltaic one of the solar cells and is then fed to an evaporation area.

10. A method according to claim 1, wherein spectral filters keep non-photo voltaically effective radiation from the photo voltaic effective solar cells in order to reduce a thermal load.

11. A method according to claim 1, wherein the cooling water is fed under pressure.

12. A method according to claim 1, wherein the cooling water is transported by capillary effect.

13. A method according to claim 1, wherein the cooling water is provided by a container that is a self-filling rain water container.

14. A method according to claim 1, wherein the cooling is at least two-tiered and comprises a closed primary circuit and open evaporation.

15. A method according to claim 14, wherein refrigerant in the primary circuit is not water or a water-like substance.

16. A method according to claim 14, wherein the refrigerant in the primary circuit is provided with spectral-filtering functions.
